(19) United States
(12) Patent Application Publication
(10) Pub. No.: US 2006/0253723 A1
(43) Pub. Date: Nov. 9, 2006

(54) Semiconductor memory and method of correcting errors for the same

(75) Inventors: Cheng-Wen Wu, Hsinchu City (TW); Chin-Lung Su, Hsichih City (TW); Yi-Ting Yeh, Hsinchu City (TW)

Correspondence Address: John S. Egbert;Egbert Law Offices, 7th Floor, 412 Main Street, Houston, TX, 77002, US

(73) Assignee: NATIONAL TSING HUA UNIVERSITY, Hsinchu (TW)

(21) Appl. No.: 11/197,657

(22) Filed: Aug. 4, 2005

(30) Foreign Application Priority Data
May 4, 2005 (TW) 094114361

(51) Int. Cl. G11C 7/10; G06F 11/00

(52) U.S. Cl. 714/1; 365/189.01

(57) ABSTRACT

A semiconductor memory employs the redundancy memory technique and the error correction code technique and method of correcting errors. The method of correcting errors reads data bits and a checking bit from a predetermined unit of a first memory array such as a main memory array, and the data bits are checked based on the checking bit to determine if there is any error. If there is an error in the data bits, the checking bit is used to correct the error and the data bits together with the checking bit are written back to the predetermined unit. If there is still error in the data bits after the read-check-write process is repeated a predetermined number of times, the predetermined unit is marked as a faulty unit and the data bits together with the checking bit are written to a second memory array such as a redundancy memory array.

### RELATED U.S. APPLICATIONS

Not applicable.

### STATEMENT REGARDING FEDERALLY SPONSORED RESEARCH OR DEVELOPMENT

Not applicable.

### REFERENCE TO MICROFICHE APPENDIX

Not applicable.

### FIELD OF THE INVENTION

The present invention relates to a semiconductor memory and method of correcting errors for the same, and more particularly, to a semiconductor memory and method of correcting errors for the semiconductor memory, which employs the redundancy memory technique and the error correction code technique.

### BACKGROUND OF THE INVENTION

Generally speaking, the memory array of the dynamic random access memory includes a main memory array and a redundancy memory array. When a faulty memory unit is verified in the main memory array at a wafer level testing or at an encapsulated die level testing before the memory is shipped out of a factory, the redundancy memory array is used to replace the faulty memory unit in the main memory array so that the yield can be increased.

In addition, the error correction code (ECC) technique is also employed in the dynamic random access memory to dynamically test and repair data stored in the memory. The error correction code technique can also correct a data error generated by an a particle except where the data error is caused by a faulty memory unit. However, the error correction code technique can only correct data errors of limited bits, i.e., the error correction code technique is not workable if a data error exceeds the limited bits. Consequently, the continuous accumulation of data errors in the memory will result in wrong data that is not repairable.

The conventional redundancy memory technique and the error correction code technique work independently in the dynamic random access memory. A technician uses the redundancy memory to replace the faulty memory unit in the main memory array during the electrical test before the memory is shipped out of the factory, while an end user can only uses the built-in error correction code circuit to correct the data error in the memory after the memory is shipped from the factory.

### BRIEF SUMMARY OF THE INVENTION

The objective of the present invention is to provide a semiconductor memory and method of correcting errors for the semiconductor memory, which employs the redundancy memory technique and the error correction code technique.

In order to achieve the above-mentioned objective and avoid the problems of the prior art, the present invention provides a semiconductor memory and a method of correcting errors in the semiconductor memory. The semiconductor memory comprises a memory circuit, a switching circuit electrically connected to the memory circuit, a controller electrically connected to the switching circuit, an encoder electrically connected to the switching circuit, and a decoder electrically connected to the switching circuit. The memory circuit includes a first memory array, a second memory array and a reconfiguring unit electrically connected to the first memory array and the second memory array. The encoder is configured to generate at least one checking bit from a plurality of data bits and to attach the checking bit to the data bits before writing into the first memory array via the switching circuit. The decoder is configured to check the correctness of the data bits based on the checking bit, to correct the error in the data bit according to the checking bit before outputting, and to transmit the corrected data bits and the checking bit to the controller. The controller includes an error correction code unit, which can write the corrected data bits and the checking bit into the second memory array via the switching circuit.

The method for correcting errors in the semiconductor memory comprises steps of reading a plurality of data bits and at least one checking bit from a predetermined unit in the first memory array, checking if there is an error in the data bits based on the checking bit, correcting the error in the data bits according to the checking bit, and writing the data bits and the checking bit back to the predetermined unit. Subsequently, after the above-mentioned steps are repeated a predetermined number of times, the predetermined unit is marked as unusable and the data bits together with the checking bit are written to a second memory array if there is still at least one error in the data bits.

### BRIEF DESCRIPTION OF THE SEVERAL VIEWS OF THE DRAWINGS

The objectives and advantages of the present invention will become apparent upon reading the following description and upon reference to the accompanying drawings in which:

FIG. 1 illustrates a functional block diagram of a semiconductor memory according to one embodiment of the present invention;

FIG. 2 illustrates a detailed architecture of a semiconductor memory according to one embodiment of the present invention;

FIG. 3 illustrates an operational state diagram of a semiconductor memory according to one embodiment of the present invention;

FIG. 4 illustrates a detailed operational state diagram of a semiconductor memory according to one embodiment of the present invention; and

FIG. 5 illustrates a detailed architecture of a configuring circuit according to one embodiment of the present invention.

### DETAILED DESCRIPTION OF THE INVENTION

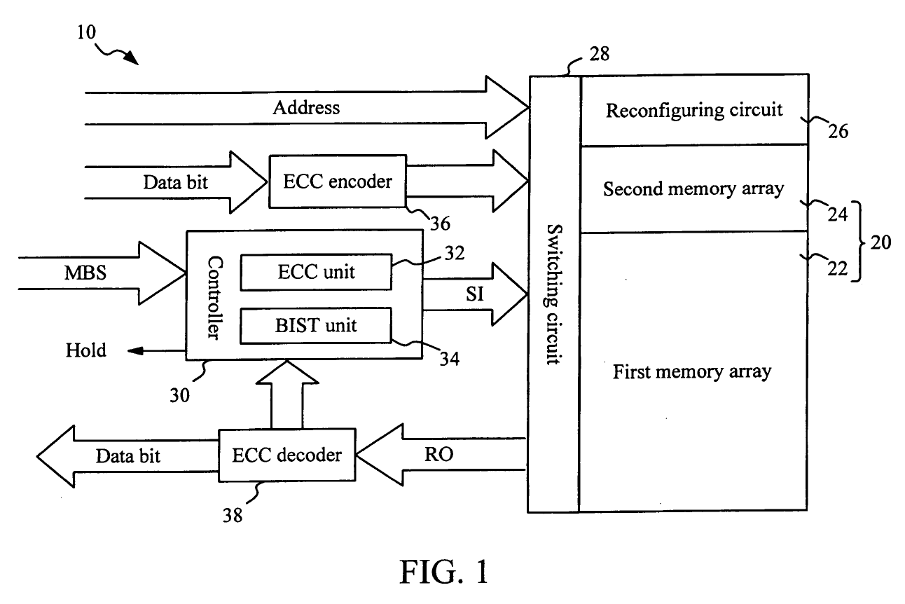

FIG. 1 illustrates a functional block diagram of a semiconductor memory 10 according to one embodiment of the present invention. The semiconductor memory 10 comprises a memory circuit 20, a switching circuit 28 electrically connected to the memory circuit 20, a controller 30 electrically connected to the switching circuit 28, an error correction code (ECC) encoder 36 electrically connected to the switching circuit 28, and an ECC decoder 38 electrically connected to the switching circuit 28. The memory circuit 20 includes a first memory array 22, and a second memory array 24. In addition, the semiconductor memory 10 further comprises a reconfiguring (RC) circuit 26 electrically connected to the first memory array 22 and the second memory array 24. The first memory array 22 is a main memory array and the second memory array 24 is a redundancy memory array. The controller 30 includes an ECC unit 32 and a built-in self-test (BIST) unit 34.

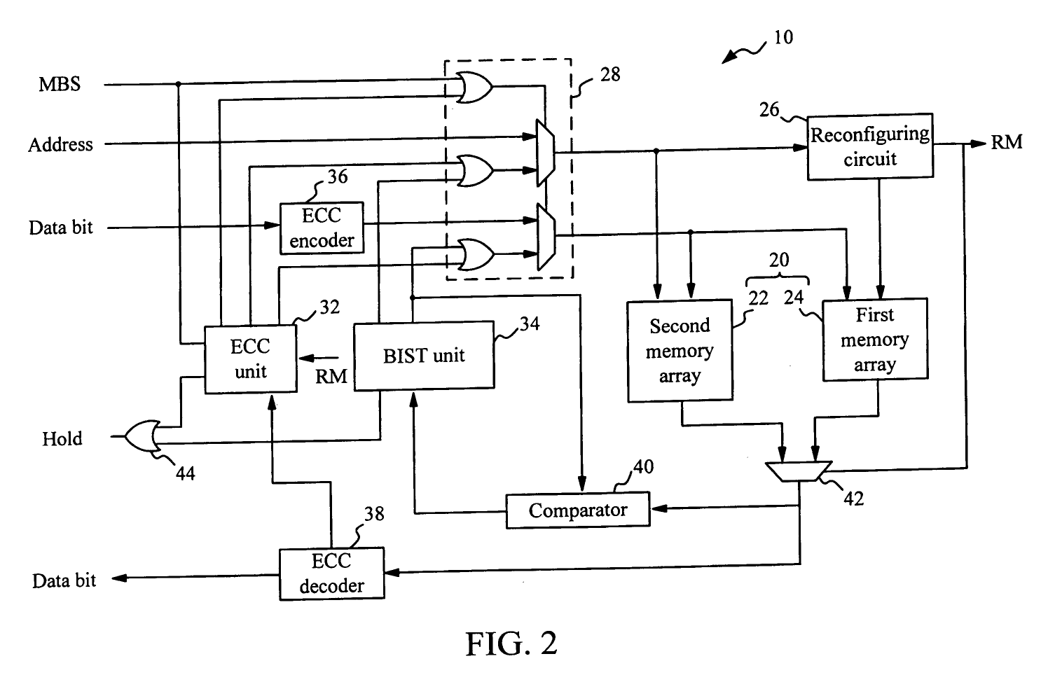

FIG. 2 illustrates a detailed architecture of the semiconductor memory 10 according to one embodiment of the present invention. The switching circuit 28 includes two multiplexers and three OR gates. The operation mode of the semiconductor memory 10 is selected by a control signal called memory BISR select (MBS) signal transmitted to the switching circuit 28. When receiving a test command from a tester, The BIST unit 34 generates testing data, which is written into the memory circuit 20 and transmitted to the comparator 40. The comparator 40 is configured to compare the testing data from the BIST unit 34 with an accessed data from the memory circuit 20 so as to check the accessing correctness of the data from the memory circuit 20. The reconfiguring circuit 26 is configured to check if an input address is indicating a faulty memory unit in the first memory array 22 and to generate a redundancy match (RM) signal accordingly, wherein a multiplexer 42 uses the RM signal to select an accessed data from the second memory array 24 as the output. In addition, the RM signal is also transmitted to the ECC unit 32 so as to check whether the address storing the accessed data is in the first memory array 22 or in the second memory array 24 once an access error occurs. During the testing process, the ECC unit 32 and the BIST unit 34 can transmit a hold signal to a host via an OR gate 44 to suspend the data input/output, i.e., holding the access operation of the memory circuit 20.

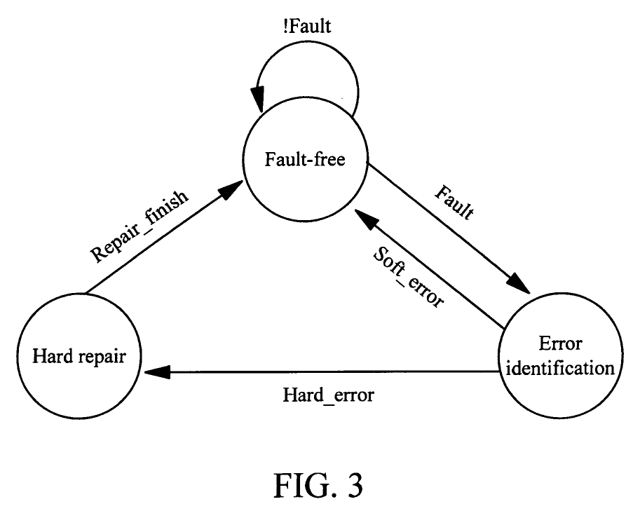

FIG. 3 illustrates an operational state diagram of a semiconductor memory 10 according to one embodiment of the present invention. Once a data error is detected during the normal operation state, i.e., fault-free state, the data error is checked to see whether it is a hard error or a soft error at the error identification state. The error is corrected using the ECC technique if the error is identified as a soft error, and the semiconductor memory 10 transits back to the fault-free state. On the contrary, the redundancy memory is used to repair the error if the error is identified as a hard error and then the semiconductor transits back to the fault-free state, i.e., the memory unit in the redundancy memory is used to replace the faulty memory unit in the main memory to store data.

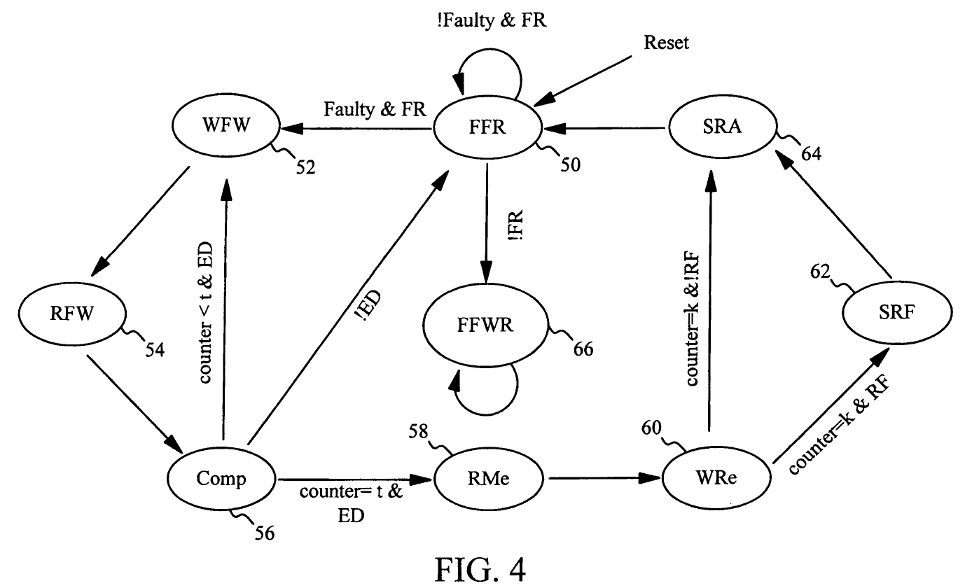

FIG. 4 illustrates a detailed operational state diagram of a semiconductor memory 10 according to one embodiment of the present invention. At the beginning, a reset signal, Reset, forces the ECC unit 32 into an initial state, i.e., FFR (!faulty & free redundancy) 50. To write a plurality of data bits into the first memory array 22 of the memory circuit 20 under the FFR state, the ECC encoder 36 generates at least one checking bit from these data bits and to attach the checking bit to the data bits before writing into a predetermined unit in the first memory array 22 via the switching circuit 28. Subsequently, the data bits together with the checking bit are read out from the predetermined unit to the ECC decoder 38 via the switching circuit 28, wherein the ECC decoder 38 checks if the data bits are correct based on the checking bit. The ECC decoder 38 outputs the data bits directly if there is not any error in the data bits. Inversely, if there is an error, the ECC decoder 38 corrects the error in the data bits according to the checking bit before outputting the data bits and transmits the corrected data bits and the checking bit to the controller 30, which will transits into a WFW (write word state) 52.

When the controller 30 enters the WFW state 52, the ECC unit 32 sends the hold signal (Hold) via the OR gate 44 to hold the normal access operation and writes the corrected data bits and the checking bit back to the predetermined unit of the first memory array 22 via the switching circuit 28. Then, the data bits and the checking bit are read out from the predetermined unit of the first memory array 22 via the switching circuit 28 at a read faulty word (RFW) state 54. Finally, the ECC decoder 38 checks if the data bits are correct at a compare (Comp) state 56. If there is still an error in the data bits, a counter is increased by one and the operation states 52-56 are repeated. If there is still an error in the read data bits after t iterations of the three operation states 52-56, the ECC unit 32 of the controller 30 identifies the fault type of the predetermined unit as a hard error, which cannot be repaired by the error correction code technique. Particularly, the iteration of the three operation states 52-56 is used to identify the fault type of the predetermined unit.

If the read data bits from the predetermined unit of the first memory array 22 are identified to be correct at the Comp state 56, the ECC unit 32 of the controller 30 directly transits back to the FFR state 50 and resets the hold signal to restart the normal access operation of the memory circuit 20. Inversely, if the ECC unit 32 of the controller 30 identifies the fault type of the predetermined unit as a hard error, it transits into a read memory (RMe) state 58 to read out the data bits and the checking bit out from the predetermined unit of the first memory array 22. Subsequently, the ECC decoder 38 corrects the data bits, which are then together with the checking bit written into an unused unit in the second memory array 24 at a write redundancy (WRe) state 60. Finally, the address of the predetermined unit in the first memory array 22 is recorded in the reconfiguring circuit 26 at a set redundancy address (SRA) state 64, and the hold signal is reset to restart the normal access operation of the memory circuit 20, i.e., the controller 30 transits back to the FFR state 50.

If the hard error is occurred in the second memory array, i.e., the redundancy memory, the data bits and the checking bit are written into another unused unit in the second memory array 24 at the WRe state 60. Then, a faulty flag (FF) is set to mark the faulty memory unit in the second memory array 24 at a set redundancy faulty (SRF) state 62. Subsequently, the address of the faulty memory unit in the second memory array 24 is recorded in the reconfiguring circuit 26 at the SRA state 64, and the hold signal is reset to restart the normal access operation of the memory circuit 20, i.e., the controller 30 transits into the FFR state 50. If there is not an unused redundancy memory unit in the second memory array 24, the controller 30 will operate at a fault-free without redundancy (FFWR) state 66. In short, if the data is stored in a first portion of a redundancy memory, the data is written into a second portion of the redundancy memory and the first portion is marked as unusable.

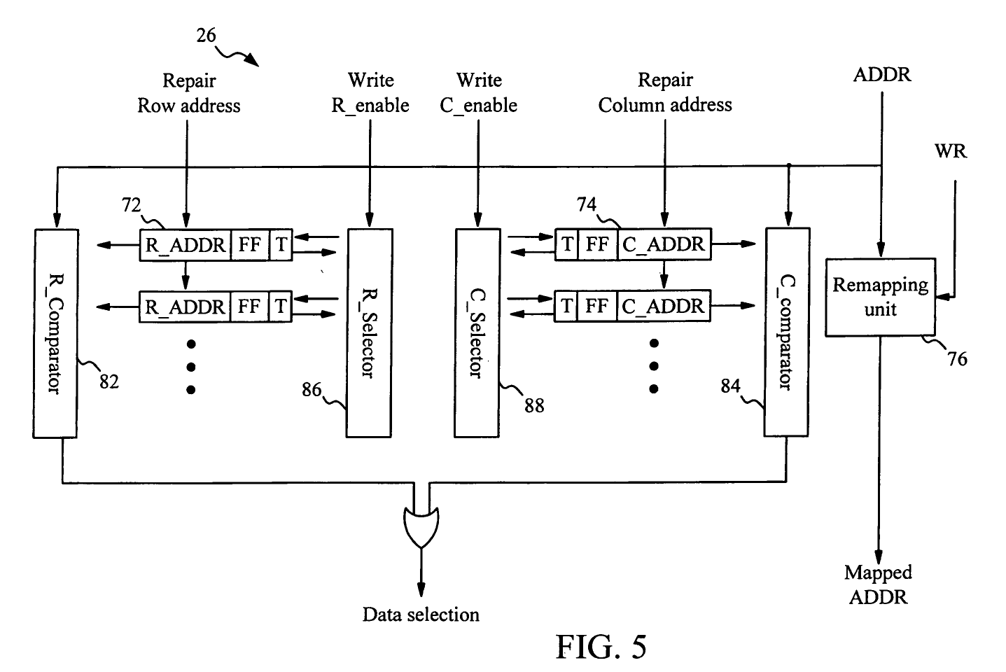

FIG. 5 illustrates a detailed architecture of a configuring circuit 26 according to one embodiment of the present invention. The row address and column address of the faulty memory unit are stored in a row address register 72 and a column address register 74, respectively. The row address register 72 and the column address register 74 both include a tag (T) field for setting if stored address already and a faulty flag (FF) field for indicating if the stored address is pointing to a memory unit in the second memory array 24. If an input address is pointing to a faulty memory unit, the remapping unit 76 transforms the input address into a remapped address, which points to a redundancy memory unit in the second memory array 24.

The row comparator 82 compares the input address with the faulty address stored in the row address register 72 (the same to the column comparator 84), a data selection signal is generated to switch the multiplexer 42 in FIG. 2 to select the accessed data from the second memory array 24 as the output if the comparison is matched. A register does not store a valid faulty address if the tag field stores an invalid value, and the row comparator 82 and the column comparator 84 will skip the registers with a tag field storing an invalid value.

When the ECC unit 32 of the controller 30 identifies the fault type of a memory unit as a hard error, a write redundancy (WR) signal is generated. When WR signal is set, the remapping unit 76 remaps the address of the faulty memory unit to an unused redundancy address, which points to an unused redundancy unit in the second memory array 24. The row selector 86 (the same to the column selector 88) selects a row address register 72 with an invalid tag field to store the faulty address of the faulty memory unit and sets the tag field of the selected row address register to be valid.

The above-described embodiments of the present invention are intended to be illustrative only. Numerous alternative embodiments may be devised by those skilled in the art without departing from the scope of the following claims.

1. A semiconductor memory, comprising:
a memory circuit being comprised of a first memory array and a second memory array;
a switching circuit electrically connected to the memory circuit;
a controller electrically connected to the switching circuit;
an encoder electrically connected to the switching circuit; and
a decoder electrically connected to the switching circuit.

2. The semiconductor memory of claim 1, wherein the encoder generates a checking bit from a plurality of data bits, attaches the checking bit to the data bits, and writes the data bits and the checking bit to the first memory array.

3. The semiconductor memory of claim 2, wherein the decoder is configured to check the correctness of the data bits according to the checking bit.

4. The semiconductor memory of claim 3, wherein the decoder is configured to repair the error of the data bit before the data bits are output and to transmit the corrected data bits and the checking bit to the controller.

5. The semiconductor memory of claim 4, wherein the controller is comprised of an error correction code unit configured to write the corrected data bits and the checking bit to the memory circuit via the switching circuit.

6. The semiconductor memory of claim 1, wherein the controller is comprised of a self-test unit configured to test if memory units in the memory circuits contains defects.

7. The semiconductor memory of claim 1, further comprising:
a reconfiguring circuit electrically connected to the first memory array and the second memory array, wherein the first memory array is a main memory array, the second memory array is a redundancy memory array.

8. A method of correcting errors for a semiconductor memory, comprising steps of:
reading a plurality of data bits and a checking bit from a predetermined unit of a first memory array;
checking if there is an error in the data bits based on the checking bit, and writing the data bits and the checking bit to the predetermined unit after correcting the error according to the checking bit if the data bits contain at least one error; and
writing the data bits and the checking bit to a second memory array if the data bits contain at least one error after repeating the steps of reading a plurality of data bits and checking if there is an error a predetermined number of times.

9. The method of correcting errors for a semiconductor memory of claim 8, further comprising:
generating a hold signal to suspend the access operation of the semiconductor memory if the data bits contains at least one error at the step of checking if there is an error.

10. The method of correcting errors for a semiconductor memory of claim 8, further comprising:
generating a reset signal to indicate that the semiconductor memory is capable of performing the access operation if the data bits are correct at the step of checking if there is an error.

11. The method of correcting errors for a semiconductor memory of claim 8, wherein the first memory array is a main memory array and the second memory array is a redundancy memory array.

12. The method of correcting errors for a semiconductor memory of claim 8, said second memory array being a redundancy memory array, said method further comprising a step of:
checking if there is any unused memory unit in the second memory array, being performed before the step of writing the data bits and the checking bit to a second memory array.

13. The method of correcting errors for a semiconductor memory of claim 8, wherein the first memory array is a first portion of a redundancy memory array and the second memory array is a second portion of the redundancy memory array.

14. The method of correcting errors for a semiconductor memory of claim 13, further comprising a step of:
marking the first portion to be unusable.

15. A method of correcting errors for a semiconductor memory, comprising steps of:
reading a plurality of data bits and a checking bit from a predetermined unit of a first memory array;
checking if there is an error in the data bits based on the checking bit;
identifying fault types of the predetermined unit; and
writing the data bits and the checking bit to a second memory array after correcting the error according to the checking bit if the fault type is a hard error.

16. The method of correcting errors for a semiconductor memory of claim 15, wherein the step of identifying fault types of the predetermined unit comprises:
writing the data bits and the checking bit to the predetermined unit after correcting the error in the data bits according to the checking bit;
reading the data bits and checking if there is an error in the data bits; and
identifying the error as the hard error if there is an error in the data bits after repeating the step of writing the data bits and the checking bit and the step of reading the data bits and checking a predetermined time.

17. The method of correcting errors for a semiconductor memory of claim 16, wherein the fault type of the predetermined unit is identified as a soft error if the data bits are correct at the step (b).

18. The method of correcting errors for a semiconductor memory of claim 17, further comprising:
generating a hold signal to suspend the access operation of the semiconductor memory if the data bits contain at least one error at the step of reading the data bits and checking.

19. The method of correcting errors for a semiconductor memory of claim 16, further comprising:
generating a reset signal to indicate that the semiconductor memory is capable of performing the access operation if the data bits are correct at the step of reading the data bits and checking.

20. The method of correcting errors for a semiconductor memory of claim 15, further comprising a step of:
checking if there is any unused memory unit in the second memory array if the fault type is identified as the hard error.

21. The method of correcting errors for a semiconductor memory of claim 15, wherein the first memory array is a main memory array and the second memory array is a redundancy memory array.

22. The method of correcting errors for a semiconductor memory of claim 15, wherein the first memory array is a first portion of a redundancy memory array and the second memory array is a second portion of the redundancy memory array.

23. The method of correcting errors for a semiconductor memory of claim 22, further comprising a step of:
marking the first portion to be unusable.
